(19) United States
(12) Patent Application Publication
(10) Pub. No.: US 2026/0202313 A1
(43) Pub. Date: Jul. 16, 2026

(54) SYSTEM AND METHOD FOR AUTO-DETECTION OF SPECTROMETER SAMPLE ACCESSORY

(71) Applicant: Agilent Technologies, Inc., Santa Clara, CA (US)

(72) Inventors: Anthony Bond, Lysterfield, Victoria (AU); Stephen Lever, Emerald, Victoria (AU)

(21) Appl. No.: 19/134,481

(22) PCT Filed: Nov. 27, 2023
(86) PCT No.: PCT/IB2023/061897

§ 371 Date: May 30, 2025

(30) Foreign Application Priority Data
Dec. 1, 2022 (AU) 2022903657

(51) Int. Cl. G01N 21/01; G01N 21/31

(52) U.S. Cl. CPC G01N 21/01; G01N 21/31; G01N 2021/0106

(57) ABSTRACT

Embodiments of the present invention are directed to a sample compartment sub-assembly for a spectrometer. The sub-assembly includes a sample support adapted to support one or more sample holders for use in the sample compartment. The sample support is associated with one or more magnets. The sub-assembly further includes a sensor assembly configured to detect the one or more magnets associated with the sample support so as to identify a mode of operating the spectrometer corresponding to the sample support.

### TECHNICAL FIELD

The present invention relates to a system and method for auto-detection of spectrometer sample accessory, a sample compartment sub-assembly for a spectrometer and a spectrometer having auto-detection capabilities.

### BACKGROUND OF INVENTION

Spectrometers such as UV-Vis-IR or UV-Vis-NIR spectrophotometer are often packaged with a range of different sample accessories having sample handling characteristics to handle different types of samples. Typically, different types of samples may require different types of analysis and thus different modes of operation using the spectrometer. For example, DNA and protein samples may be analysed using different quantitation methods, including nucleic acid quantitation, protein quantitation, Lowry method, BCA method, CBB method, Biuret method or UV absorption method and so forth. Other types of solid and/or liquid samples may require analysis by measuring absorbance or transmittance at a single wavelength or at multiple wavelengths, or measure changes in absorbance, transmittance, or energy as a function of time.

Conventionally, once the sample accessories for handling one or more samples are set up by an operator, the appropriate mode of operation for the spectrometer is manually selected each time a new sample accessory setup is used. This can be time consuming and prone to manual handling errors.

Embodiments of the invention may provide a sample component sub-assembly, a spectrometer, a system and a method of determining a mode of operation for a spectrometer which overcomes or ameliorates one or more of the disadvantages or problems described above, or which at least provides the consumer with a useful choice.

A reference herein to a patent document or any other matter identified as prior art, is not to be taken as an admission that the document or other matter was known or that the information it contains was part of the common general knowledge as at the priority date of any of the claims.

### SUMMARY OF INVENTION

According to one aspect of the invention, there is provided a sample compartment sub-assembly for a spectrometer, the sub-assembly including a sample support adapted to support one or more sample holders for use in the sample compartment, the sample support being associated with one or more magnets, and a sensor assembly configured to detecting the one or more magnets associated with the sample support so as to identify a mode of operating the spectrometer corresponding to the sample support.

Advantageously, the sensor assembly enables automatic detection of the one or more magnets to determine the particular type of sample support, a particular set-up of the sample support and/or a particular sample carried by the one or more sample holders being deployed in the sample compartment of the spectrometer, thereby enabling a processor of the spectrometer to determine a suitable mode of operation for the spectrometer. The automatic detection reduces manual operation and provides improved equipment setup efficiency and accuracy.

In one embodiment, the sensor assembly may include one or more magnetic field sensors for detecting the one or more magnets. Any suitable types of magnetic field sensors may be used. For example, the magnetic field sensors may include any one or more of Hall Effect sensors, reed contact switches, semiconducting magnetoresistors, ferromagnetic magnetoresistors, magnetic encoders, magnetoresistive position sensors. Alternatively, one or more optical sensors may be used in the sensor assembly. In other embodiments, electrical contacts or electro-mechanical switches may be used in the sensor assembly. In this embodiment, one or more terminals may be provided in place of the one or more magnets. The electrical contacts or electro-mechanical switches may contact one or more of the terminals to determine a mode of operation for the spectrometer.

The sub-assembly may further include a base mount for mounting to a base of the sample compartment of the spectrometer. The base mount may be associated with the sensor assembly. In particular, the sensor assembly may be mounted in the base mount.

Alternatively, the sensor assembly may be mounted to a wall or a floor of the sample compartment.

The base mount may define an aperture for exposing a sensor portion of the sensor assembly such that the sensor portion is aligned with the one or more magnets in use so as to facilitate detection of the one or more magnets by the sensor assembly.

In use, the sample support may be secured to the base mount via any suitable fastening means. For example, clamps, brackets, screws, nuts, rivets, or any combination thereof may be used. In one embodiment, the sample support may include a mounting magnet for securing the sample support to the base mount.

The one or more magnets may be mounted to an underside of the sample support for detection by the sensor assembly. Moreover, the one or more magnetic field sensors may be arranged such that a position of each magnetic field sensor corresponds to a position of a magnet.

The magnets may be arranged in any suitable manner. For example, the magnets may be arranged in one or more arrays, rows and/or columns, aligned or misaligned, or in any random configuration.

The sample support may be associated with a plurality of magnets. The plurality of magnets may be arranged in a row. The sub-assembly may further include a magnetic keeper to mask one or more of the plurality of magnets so as to provide a plurality of unique combinations of exposed magnets for detection by the sensor assembly. Each combination may be associated with a specific mode of operation for the spectrometer.

Advantageously, the keeper may be arranged to provide a particular combination of exposed magnets associated with a specific mode of operation which corresponds to, and is suitable for, analysing a particular sample arranged in a particular manner with respect to the sample support. This enables auto-detection of the appropriate mode of operation for the spectrometer as soon as the sample support carrying the particular sample(s) is loaded into the sample compartment of the spectrometer.

The magnetic keeper may comprise a mask defining a plurality of apertures therein. Movement of the mask relative to the plurality of magnets may change the combination of magnets exposed through the apertures thereby providing a plurality of unique combinations of exposed magnets. In particular, movement of the mask may include any one or more of translation, rotation and reversing of the mask in combination.

The mask may be of any suitable shape and size. In one embodiment, the mask is a generally rectangular plate. The mask may be made from a ferromagnetic material such as iron.

The sensor assembly may be coupled to a controller of the spectrometer to determine or facilitate a determination of a mode of operation for the spectrometer corresponding to the sample support. In particular, when the sensor assembly detects a specific combination of exposed magnets, the sensor assembly generates and transmits a signal to the controller of the spectrometer. The signal may be any suitable signal. In one embodiment, the signal is a unique binary code corresponding to the detected unique combination of exposed magnets. The controller may determine a mode of operation for the spectrometer that corresponds to the signal received from the sensor assembly. The controller may communicate the signal to an external processor for determining a suitable mode of operation for the spectrometer.

According to another aspect of the invention, there is provided a spectrometer comprising a sample compartment sub-assembly as described herein.

According to a further invention, there is provided a spectrometer having a sample compartment, the spectrometer including
a sample support adapted to support one or more sample holders for use in the sample compartment, the sample support being associated with one or more magnets,
a base mount adapted for mounting to a base of the sample compartment of the spectrometer, the base mount having a sensor assembly associated therewith configured to detect the one or more magnets associated with the sample support so as to identify a mode of operating the spectrometer corresponding to the sample support.

The spectrometer may include a plurality of sample supports, each sample support being adapted to support one or more sample holders for holding a type of sample and/or to facilitate a specific type of sample analysis.

In one embodiment, the spectrometer may be a UV-Vis-IR or UV-Vis-NIR spectrophotometer. In another embodiment, the spectrometer may be a laser direct infrared (LDIR) spectrometer. In a further embodiment, the spectrometer may be a Fourier transform infrared (FTIR) spectrometer.

According to another aspect of the invention, there is provided a system of auto-recognition of a sample accessory for a spectrometer, the system including
a plurality of magnets associated with the sample accessory, and
a sensor assembly mounted in a sample compartment of the spectrometer, the sensor assembly being configured to detect the plurality of magnets when the sample accessory is used in the sample compartment to determine a mode of operating the spectrometer corresponding to the sample accessory.

The system may further include a magnetic keeper configured to mask one or more of the plurality of magnets so as to provide a plurality of unique combinations of exposed magnets for detection by the sensor assembly, each combination being associated with a specific mode of operation for the spectrometer.

The sensor assembly may be configured to generate a unique binary code corresponding to a unique combination of exposed magnets detected by the sensor assembly.

The system may further include a processor. The processor may be configured to receive the unique binary code, determine a mode of operation based on the received unique binary code, and set operating parameters and a data collection method for the spectrometer based on the determined mode of operation. The processor may receive the unique binary code via a controller of the spectrometer.

According to yet another aspect of the invention, there is provided a method of determining a mode of operation for a spectrometer, the method comprising
providing a sample support for supporting one or more sample holders for use in the sample compartment, the sample support being associated with one or more magnets, and
detecting the one or more magnets using a sensor assembly so as to identify the mode of operating the spectrometer corresponding to the sample support.

The method may further comprise mounting a magnetic keeper over the one or more magnets such that a unique combination of the one or more magnets is exposed via one or more apertures of the magnetic keeper, the unique combination being associated with a specific mode of operation for the spectrometer, wherein detecting the one or more magnets includes detecting the unique combination using the sensor assembly.

The method may further comprise moving the magnetic keeper relative to the one or more magnets such that a different unique combination of the one or more magnets is exposed via one or more apertures of the magnetic keeper, the different unique combination being associated with a different mode of operation for the spectrometer.

Moving the magnetic keeper relative to the one or more magnets may include one or more of translating, rotating and/or reversing the magnetic keeper.

The method may further include generating, via the sensor assembly, a unique binary code corresponding to the unique combination of exposed magnets detected by the sensor assembly.

According to yet another aspect of the invention, there is provided a system for determining a mode of operation for a spectrometer, the system including
one or more magnets mounted to a sample support, the sample support being adapted to support one or more sample holders for use in a sample compartment of the spectrometer, and
a sensor assembly for detecting the one or more magnets and generating a signal, and
a controller for receiving the signal and identifying a mode of operating the spectrometer corresponding to the sample support based on the signal.

In order that the invention may be more readily understood and put into practice, one or more preferred embodiments thereof will now be described, by way of example only, with reference to the accompanying drawings.

It will be appreciated that for simplicity and clarity of illustration, where considered appropriate, reference numerals may be repeated among the figures to indicate corresponding or analogous elements.

### BRIEF DESCRIPTION OF DRAWINGS

FIGS. 1A and 1B illustrate a spectrometer according to one embodiment of the invention having a sample compartment.

FIGS. 2A to 2C illustrate a sample support of a sub-assembly having magnets associated therewith according to one embodiment of the invention.

FIGS. 3A to 3D illustrate a magnetic keeper associated with the sample support as shown in FIGS. 2A to 2D.

FIGS. 4A and 4B illustrate a base mount of the sub-assembly having a sensor assembly associated therewith according to one embodiment of the invention.

FIG. 5 illustrates a cross-sectional view of the sub-assembly including a sample support and base mount as shown in FIGS. 2A to 3D.

FIG. 6 is a schematic diagram illustrating a system for determining a mode of operation for a spectrometer according to an embodiment of the invention.

FIG. 7 is a flow diagram illustrating a method of determining a mode of operation for a spectrometer according to an embodiment of the invention.

### DETAILED DESCRIPTION

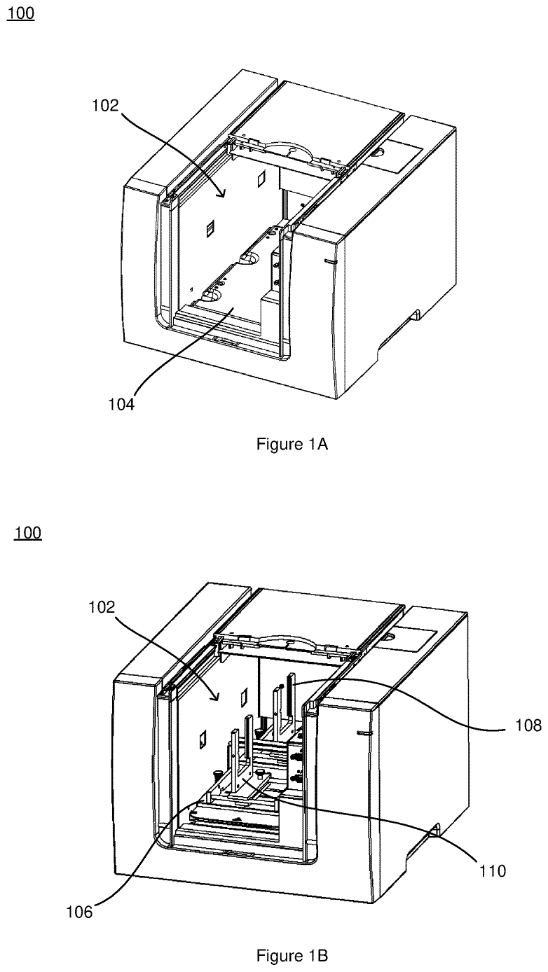

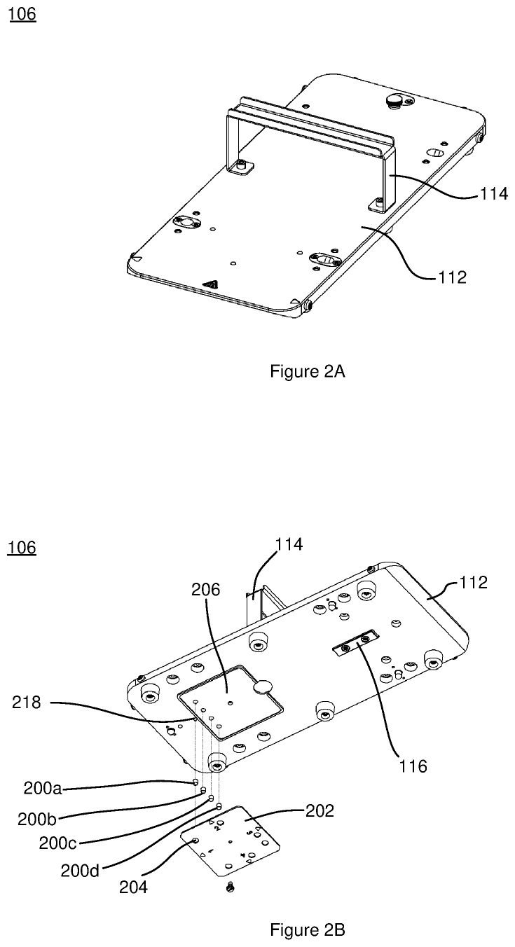

A spectrometer 100 having a sample compartment 102 is illustrated in FIGS. 1A and 1B. The sample compartment 102 provides space in the spectrometer to load one or more samples for analysis by the spectrometer 100. As more clearly shown in FIG. 1A, the spectrometer 100 further includes a base mount 104 adapted for mounting to a base portion of the spectrometer 100. As more clearly shown in FIG. 1B, the spectrometer 100 further includes a sample support 106 adapted to support sample holders 108, 110. Whilst FIG. 1B illustrates that the sample support 106 supports two sample holders 108, 110, it is to be understood that the sample support 106 can be configured to support any suitable number of sample holders simultaneously. Typically, the types and total number of sample holders 108, 110 mounted to the sample support 106 can be changed to suit the particular type of analysis to be carried out in the spectrometer 100.

The spectrometer 100 may be a UV-Vis-IR or UV-Vis-NIR spectrophotometer. Alternatively, the spectrometer 100 may be a laser direct infrared (LDIR) spectrometer or a Fourier transform infrared (FTIR) spectrometer.

FIGS. 2A to 2C more clearly illustrates the sample support 106 with the sample holders 108, 110 removed. The sample support 106 has a generally rectangular base 112 shaped and sized to fit into the sample compartment 102 of the spectrometer 100. The sample support 106 further includes a handle 114 mounted to the base 112 to facilitate movement of the sample support 106 in and out of the sample compartment 102. Typically, a spectrometer 100 may include a plurality of different sample supports 106 and a plurality of different sample holders 108, 110 (also collectively referred to herein as sample accessories) which can be used in any combination to enable a desired sample analysis to be carried out by the spectrometer 100.

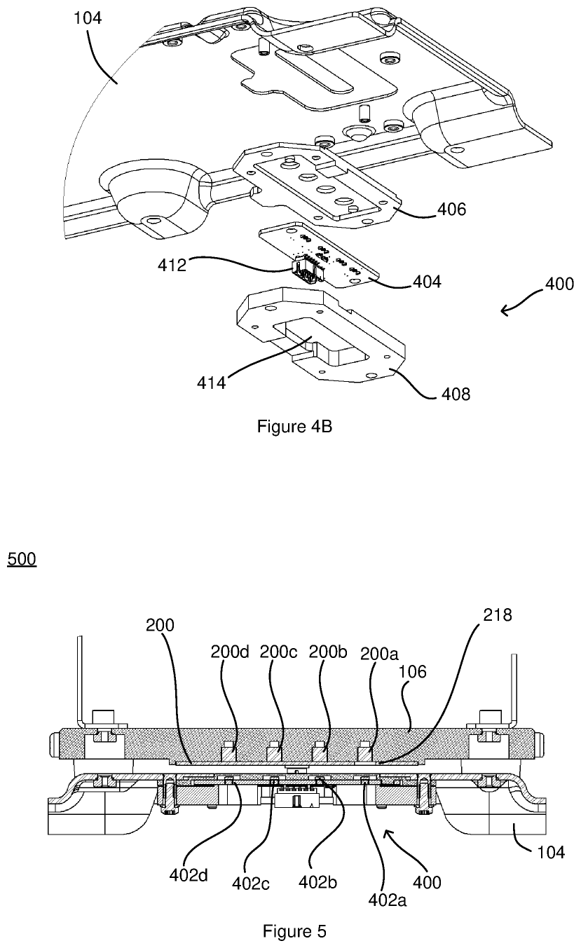

As illustrated in FIG. 2B, the sample support 106 provides a plurality of magnets 200a, 200b, 200c, 200d mounted to an underside of the sample support 106. In the particular embodiment shown, the plurality of four magnets 200a, 200b, 200c, 200d are arranged in a row and secured to corresponding recesses in the base 112 of the sample support 106. As described in further detail below with reference to FIGS. 4A to 5, a specific combination of the magnets (from a plurality of combinations of magnets) can be detected by a sensor assembly to determine a suitable mode of operation for the spectrometer 100.

To provide the plurality of combinations of magnets, a magnetic keeper 202 is provided to mask one or more of the plurality of magnets 200a, 200b, 200c, 200d. In the particular embodiment illustrated, the magnetic keeper 202 is a generally rectangular mask having a plurality of apertures 204 defined therein. The apertures 204 are positioned adjacent a periphery of the mask and are spaced along each of the four edges/sides of the mask 202.

A recessed portion 206 in the sample support 106 is shaped and sized to receive the magnetic keeper 202 therein. As more clearly shown in FIG. 2C, when the magnets 200a, 200b, 200c, 200d and magnetic keeper 202 are both secured to the underside of the sample support 106, the magnetic keeper 202 is placed over the row of magnets 200a, 200b, 200c, 200d. One or more of the plurality of magnets 200a, 200b, 200c, 200d is exposed through the one or more apertures of the magnetic keeper 202 when the magnetic keeper 202 is placed over the magnets 200a, 200b, 200c, 200d.

The apertures are located along each edge of the magnetic keeper 202. Moreover, the apertures are positioned to align with different ones of the plurality magnets 200a, 200b, 200c, 200d when the magnetic keeper 202 is moved with respect to the magnets 200a, 200b, 200c, 200d. In particular, the sample support 106 includes a marker 208 proximate the row of magnets 200a, 200b, 200c, 200d to facilitate proper positioning and alignment of the magnetic keeper 202 with respect to the magnets 200a, 200b, 200c, 200d. For example, when a first side 210 of the magnetic keeper 202 is aligned with the marker 208 as shown in FIG. 2C, the aperture 218 proximate the first side 210 is aligned with one of the magnets 200a and only the aligned magnet 200a is exposed via the aperture 218, and the remainder of the magnets 200b, 200c, 200d are covered by magnetic keeper 202 such that the magnetic field of the covered magnets 200b, 200c, 200d cannot be detected by a magnetic field sensor assembly. In this position, only the magnetic field of the exposed magnet 200a can be detected by a magnetic field sensor assembly. Accordingly, the unique combination of exposed magnets detectable by the sensor assembly in this scenario is a single magnet 200a. Upon detection of the unique combination (i.e. single magnet 200a), the sensor assembly may generate the unique binary code ‘1000’.

Similarly, when the magnetic keeper 202 is rotated such that a second side 216 of the magnetic keeper 202 is aligned with the marker 208, the aperture corresponding to the second side 216 would be aligned with a different one of the magnets 200b and only the aligned magnet 200b would be exposed via the aperture 220, and the remainder of the magnets 200a, 200c, 200d would be covered by the magnetic keeper 202 such that the magnetic field of the covered magnets 200a, 200c, 200d would not be detectable by the magnetic field sensor assembly. In this position, only the magnetic field of the exposed magnet 200b would be detectable by the magnetic field sensor assembly. Accordingly, the unique combination of exposed magnets detectable by the sensor assembly in this scenario is a single magnet 200b. Upon detection of the unique combination (i.e. single magnet 200b), the sensor assembly may generate the unique binary code ‘0100’.

When the magnetic keeper 202 is further rotated such that a third side 214 of the magnetic keeper 202 is aligned with the marker 208, the two apertures 222, 224 corresponding to the third side 214 would be aligned with two of the magnets 200a, 200b and only the aligned magnets 200a, 200b would be exposed via the apertures 222, 224 respectively. The remainder of the magnets 200c, 200d would be covered by the magnetic keeper 202 such that the magnetic field of the covered magnets 200c, 200d would not be detectable by the magnetic field sensor assembly. In this position, only the magnetic field of the exposed magnets 200a, 200b would be detectable by the magnetic field sensor assembly. Accordingly, the unique combination of exposed magnets detectable by the sensor assembly in this scenario include magnets 200a, 200b. Upon detection of the unique combination (i.e. magnets 200a, 200b), the sensor assembly may generate the unique binary code ‘1100’.

When the magnetic keeper 202 is further rotated such that a fourth side 212 of the magnetic keeper 202 is aligned with the marker 208, the two apertures 226, 228 corresponding to the fourth side 212 would be aligned with a different two of the magnets 200a, 200c and only the aligned magnets 200a, 200c would be exposed via the apertures 228, 226 respectively. The remainder of the magnets 200b, 200d would be covered by the magnetic keeper 202 such that the magnetic field of the covered magnets 200b, 200d would not be detectable by the magnetic field sensor assembly. In this position, only the magnetic field of the exposed magnets 200a, 200c would be detectable by the magnetic field sensor assembly. Accordingly, the unique combination of exposed magnets detectable by the sensor assembly in this scenario include magnets 200a, 200c. Upon detection of the unique combination (i.e., magnets 200a, 200c), the sensor assembly may generate the unique binary code ‘1010’.

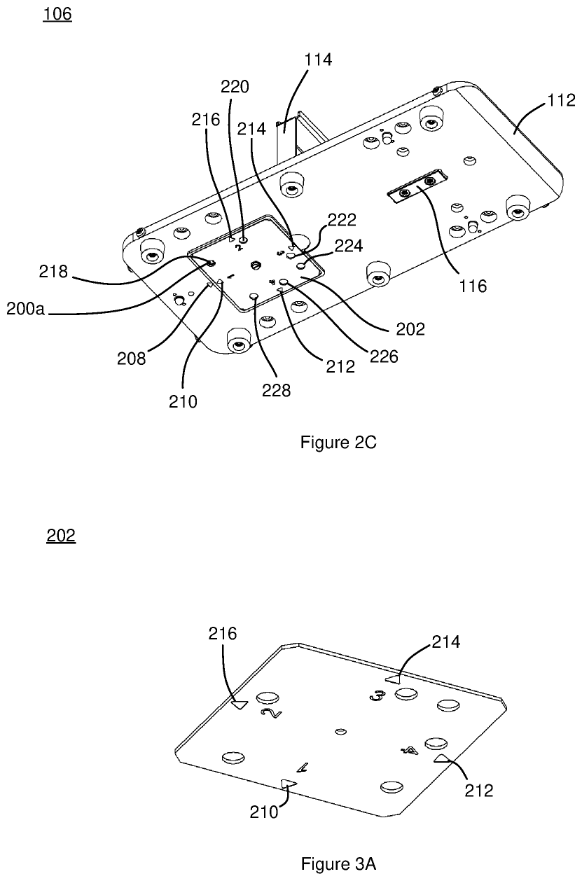

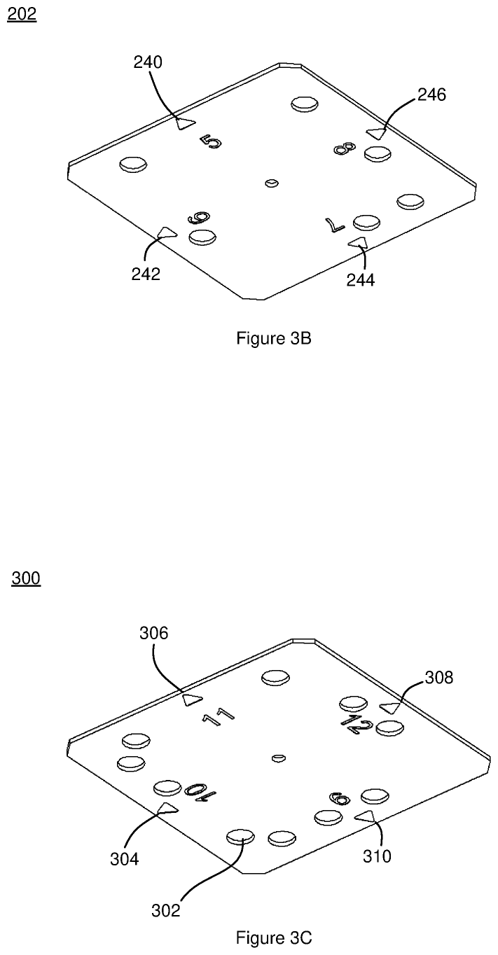

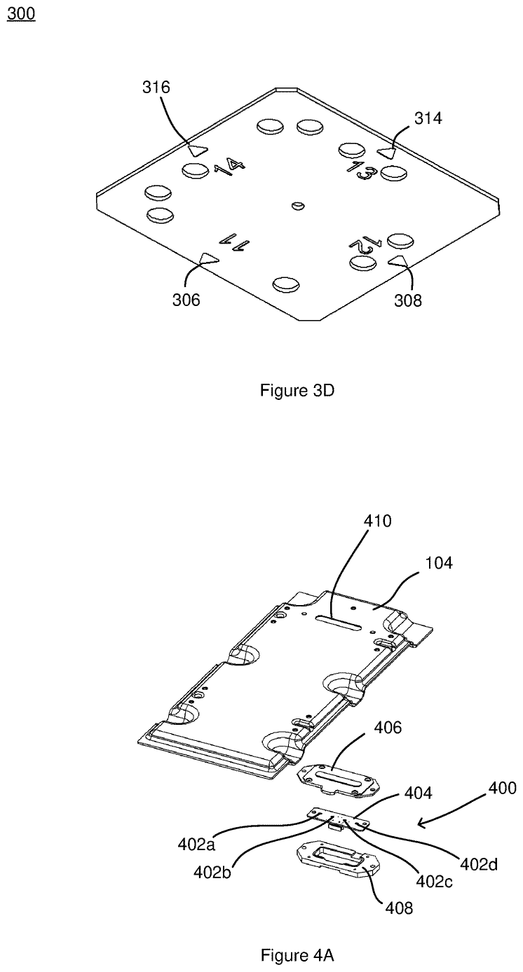

In the examples described above, the magnetic keeper 202 can be rotated to provide four unique combinations of exposed magnets from the plurality of magnets 200a, 200b, 200c, 200d. The magnetic keeper 202 can be reversed and rotated to provide a further four unique combinations of exposed magnets. As illustrated in FIGS. 3A to 3D, a plurality of magnetic keepers 202 may be provided to provide any suitable number of unique combinations of exposed magnets.

In particular, a close-up view of the magnetic keeper 202 is illustrated in FIG. 3A. FIG. 3B illustrates the reverse of magnetic keeper 202, in which a further four unique combinations of exposed magnets can be provided when each of the four respective sides 240, 242, 244, 246 are aligned with the marker 208 in use.

A different magnetic keeper 300 is illustrated in FIGS. 3C and 3D. FIG. 3C illustrates a first face of the magnetic keeper 300 in which a different number and arrangement of apertures 302 are provided along each of the four sides 304, 306, 308, 310. When the first face of the magnetic keeper 300 is facing outwardly when attached to the base 112 of the sample support 106, a further four unique combinations of exposed magnets can be provided when each of the four respective sides 304, 306, 308, 310 are aligned with the marker 208 in use.

As shown in FIG. 3D, a second face of the magnetic keeper 300 opposite the first face provides additional options for unique combinations of exposed magnets in use. In particular, two additional unique combinations of exposed magnets can be provided when each of the two respective sides 314, 316 are aligned with the marker 208 when the keeper 300 is mounted to the base 112 of the sample support 106 with the second face facing outwardly. Side 306 provides the same combination of exposed magnets regardless of whether the first face or the second face of the keeper 300 is facing outwardly when attached to the sample support 106. Similarly, side 308 also provides the same combination of exposed magnets regardless of whether the first face or the second face of the keeper 300 is facing outwardly when attached to the sample support 106.

In other embodiments, more than four magnets may be provided by the sample support 106 to allow for a higher number of unique combinations when placed together with a magnetic keeper, to allow selection of a higher range of modes of operation for the spectrometer, if required.

As shown in FIG. 4A, the spectrometer 100 further includes a sensor assembly 400 configured to detect the one or more magnets 200a, 200b, 200c, 200d associated with the sample support 106 so as to identify a mode of operating the spectrometer 100 corresponding to the sample support 106. In the embodiment shown, the sensor assembly 400 includes a plurality of magnetic field sensors 402a, 402b, 402c, 402d. In particular, the sensor assembly 400 includes four magnetic field sensors 402a, 402b, 402c, 402d for detecting the different combinations of exposed magnets provided by the interoperation between the magnetic mask 202 and the magnets 200a, 200b, 200c, 200d mounted to the underside of the sample support 106.

Any suitable magnetic field sensors 402a, 402b, 402c, 402d may be used. In one embodiment, Hall Effect sensors may be used to detect the magnets 200a, 200b, 200c, 200d.

The sensor assembly 400 includes a printed circuit board (PCB) 404. The four magnetic field sensors 402a, 402b, 402c, 402d are provided by the PCB 404. The PCB 404 is protected and held in place between a cover 406 and a seat 408. The assembly including the cover 406, PCB 404, and seat 408 is mounted to an underside of the base mount 104. The base mount 104 defines an opening 410 to expose the magnetic field sensors 402a, 402b, 402c, 402d and facilitate detection of the magnets 200a, 200b, 200c, 200d.

An underside of the cover 406 is illustrated in FIG. 4B. The cover 406 includes a plurality of recesses, each recess being sized and positioned to align with each one of the magnetic field sensors 402a, 402b, 402c, 402d respectively. The cover 406 is typically made from a non-magnetic material and serves to protect the magnetic field sensors 402a, 402b, 402c, 402d from the ingress of dust and liquids.

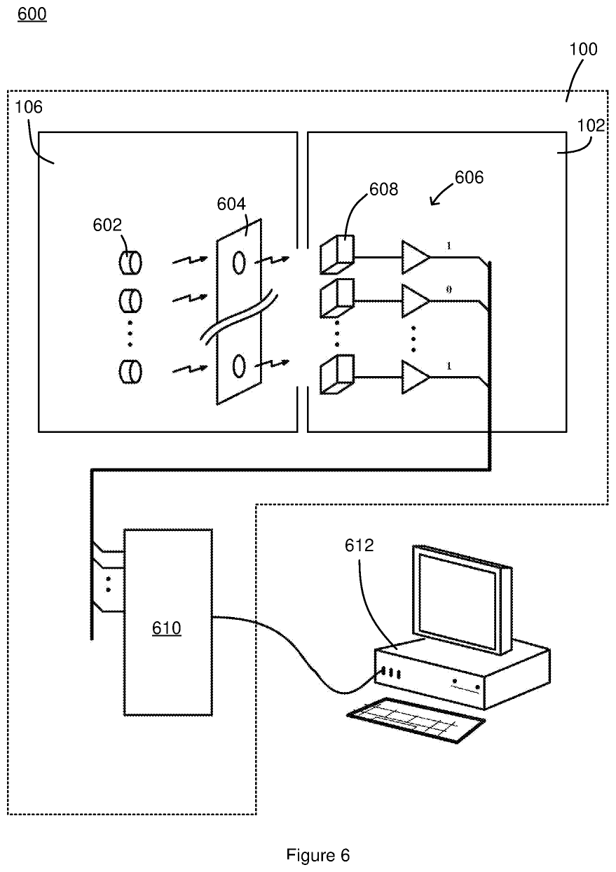

The PCB 404 further includes a port 412 to facilitate wired connection of the PCB 412 to a controller 610 of the spectrometer 100 as will be described in further detail below with reference to FIG. 6. The seat 408 defines an opening 414 to accommodate the port 412 and the wired connection from the PCB 404 to the controller 610.

In use, the sample support 106 is secured to the base mount 104 via a mounting magnet 116 (see FIGS. 2C and 2B), although it is to be understood that any suitable fastening means may be used to secure the sample support 106 to the base mount 104. As shown in FIG. 5, each of the magnetic field sensors 402a, 402b, 402c, 402d is aligned with a respective one of the magnets 200a, 200b, 200c, 200d. In the embodiment shown in FIG. 5, the magnetic keeper 200 is covering three of the magnets 200b, 200c, 200d, and only one of the magnets 200a is exposed via aperture 218. In this scenario, only one of the magnetic field sensors 402a in the sensor assembly 400 would detect the presence of a magnetic field. A corresponding unique binary code (i.e. ‘1000’) is generated by the sensor assembly 400 and sent to the controller 610.

A schematic diagram of a system 600 for determining a mode of operation for a spectrometer 100 is illustrated in FIG. 6. The system 600 includes a plurality of magnets 602 mounted to a sample support 106. A magnetic keeper 604 can be removably mounted over the magnets 602 to provide a plurality of unique combinations of exposed magnets 602 as described above with reference to FIGS. 2B to 3D.

The system 600 further includes a sensor assembly 606 provided in the sample compartment of the spectrometer 100. The sensor assembly 606 may be mounted to a base mount 104. Alternatively, the sensor assembly 606 may be provided elsewhere in the spectrometer. For example, the sensor assembly 606 may be mounted directly to a floor of the sample compartment.

The sensor assembly 606 includes a plurality of magnetic field sensors 608. Each magnetic field sensor 608 corresponds to a magnet 602. The positioning of the magnets 602 and the magnetic field sensors 608 are such that each magnet is aligned with a corresponding magnetic field sensor so as to facilitate of detection of the magnetic field associated with each magnet by the corresponding aligned magnetic field sensor 608. As mentioned, the interoperation between the magnetic keeper 604 and the magnets 602 provide a plurality of unique combinations of exposed magnets 602 for detection by the sensor assembly 400.

The system further includes a controller 610. Upon detection of each unique combination of exposed magnets 602, the sensor assembly 606 generates a unique binary code, which is transmitted to a controller 610 to determine an appropriate mode of operation for the spectrometer 100. The determined mode of operation is then transmitted from the controller 610 to an external processor 612. Alternatively, the controller 610 may transmit the unique binary code directly to the processor 612, and the processor 612 determines the corresponding mode of operation for the spectrometer 100. The external processor 612 is configured to set and control operations of the spectrometer 100 based on the determined mode of operation.

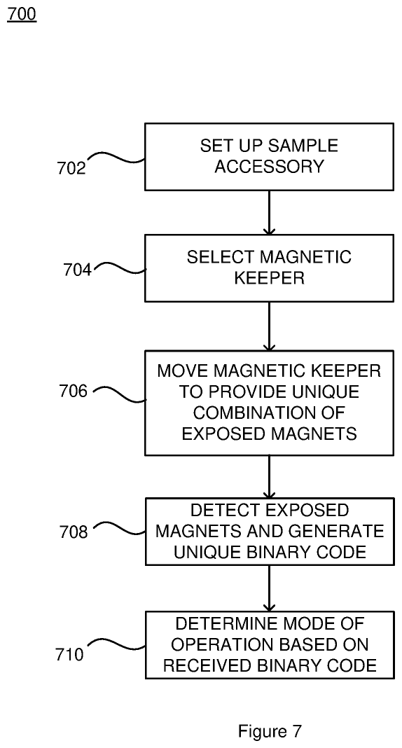

A method 700 of determining a mode of operation for a spectrometer 100 will now be described with reference to FIG. 7.

In practice, a spectrometer 100 may have a plurality of different types of sample supports 106 and sample holders 110 (herein collectively referred to as sample accessories) associated therewith. The sample accessories may be used in any combination to provide a particular setup suitable for analysing one or more specific types of samples in the spectrometer 100. Each sample accessory may have different sample handling characteristics. For example, different sample accessories may be adapted to handle solids and/or liquids for measurement in either transmission or reflectance modes by a UV-Vis-IR spectrometer.

At step 702, an operator sets up a sample accessory by choosing a specific sample support 106 and one or more sample holders 110 for mounting to the sample support 106.

At step 704, the operator selects the appropriate magnetic keeper 202 to be used with the sample accessory. As illustrated in FIGS. 3A to 3C, each side of the magnetic keeper 202 is numbered and each number is associated with a particular mode of operation so that the operator can determine the appropriate side of the keeper 202 for alignment with the marker 208 to enable auto-detection of the desired mode of operation.

At step 706, the operator sets up the sample accessory for a particular sample analysis. To do this, the operator moves the magnetic keeper 202 so that a relevant edge/side of the keeper 202 is aligned with the marker 208 on the sample holder 106 to provide a desired mode of operation. Once the magnetic keeper 202 is properly aligned and secured in place, the configured sample accessory is loaded into the sample compartment 102. The mounting magnet 116 secures the sample support 106 to the base mount 104 in the sample compartment 102.

At step 708, the sensor assembly 400 detects the unique combination of exposed magnets from the sample accessory and generates a unique binary code for transmission to the controller 610. For example, for each magnetic field sensor 608 that detects the presence of a magnetic field from a corresponding magnet 602, the sensor assembly 400 generates a binary number ‘1’ corresponding to that magnetic field sensor 608. Otherwise, the sensor assembly 400 generates a binary number ‘0’ for that magnetic field sensor. The combination of binary numbers from each of the magnetic field sensors 608 provides a unique binary code for transmission to the controller 610.

At step 710, the controller 610 (e.g. microprocessor) receives the binary code and transmits the binary code to a processor 612. Typically, the processor 612 includes specialist software application for setting and controlling the operating parameters for the spectrometer 100 and for collecting photometric data from the spectrometer 100. The processor 612 determines a mode of operation corresponding to the received unique binary code. A lookup table having a combination of unique binary codes and their corresponding modes of operation may be saved in memory. When the processor 612 receives a unique binary code from the sensor assembly 400, the processor 612 can determine the corresponding mode of operation for the spectrometer 100 based on the lookup table.

When the sample accessory is removed and replaced with a new sample accessory associated with a different unique binary code, the detection of a new unique combination of magnets and the generation of a new code by the sensor assembly 400 automatically triggers a new mode of operation, in which different operating parameters and data collection methods may be set by the processor 612. This reduces manual setup and calibration by the operator, thereby reducing operating time and manual handling errors.

In practice, the magnetic keeper 202 may be preset to provide a specific unique combination of exposed magnets, for example if the associated sample support 106 is intended for a specific mode of operation when used in the spectrometer 100. In other instances, an operator may set the specific mode of operation by moving the magnetic keeper 202 as described herein.

### Interpretation

This specification, including the claims, is intended to be interpreted as follows:

Embodiments or examples described in the specification are intended to be illustrative of the invention, without limiting the scope thereof. The invention is capable of being practised with various modifications and additions as will readily occur to those skilled in the art. Accordingly, it is to be understood that the scope of the invention is not to be limited to the exact construction and operation described or illustrated, but only by the following claims.

The mere disclosure of a method step or product element in the specification should not be construed as being essential to the invention claimed herein, except where it is either expressly stated to be so or expressly recited in a claim.

The terms in the claims have the broadest scope of meaning they would have been given by a person of ordinary skill in the art as of the relevant date.

The terms “a” and “an” mean “one or more”, unless expressly specified otherwise.

Neither the title nor the abstract of the present application is to be taken as limiting in any way as the scope of the claimed invention.

Where the preamble of a claim recites a purpose, benefit or possible use of the claimed invention, it does not limit the claimed invention to having only that purpose, benefit or possible use.

It should be noted that terms of degree such as “generally”, “substantially”, “about” and “approximately” as used herein mean a reasonable amount of deviation of the modified term such that the end result is not significantly changed. These terms of degree should be construed as including a deviation of the modified term if this deviation would not negate the meaning of the term it modifies.

In the specification, including the claims, the term “comprise”, and variants of that term such as “comprises” or “comprising”, are used to mean “including but not limited to”, unless expressly specified otherwise, or unless in the context or usage an exclusive interpretation of the term is required.

Furthermore, the recitation of any numerical ranges by endpoints herein includes all numbers and fractions subsumed within that range (e.g. 1 to 5 includes 1, 1.5, 2, 2.75, 3, 3.90, 4, and 5). It is also to be understood that all numbers and fractions thereof are presumed to be modified by the term “about” which means a variation up to a certain amount of the number to which reference is being made if the end result is not significantly changed.

As used herein, the wording “and/or” is intended to represent an inclusive-or. That is, “X and/or Y” is intended to mean X or Y or both, for example. As a further example, “X, Y, and/or Z” is intended to mean X or Y or Z or any combination thereof.

The disclosure of any document referred to herein is incorporated by reference into this patent application as part of the present disclosure, but only for purposes of written description and enablement and should in no way be used to limit, define, or otherwise construe any term of the present application where the present application, without such incorporation by reference, would not have failed to provide an ascertainable meaning. Any incorporation by reference does not, in and of itself, constitute any endorsement or ratification of any statement, opinion or argument contained in any incorporated document.

1. A sample compartment sub-assembly for a spectrometer, the sub-assembly including
a sample support adapted to support one or more sample holders for use in the sample compartment, the sample support being associated with one or more magnets, and
a sensor assembly configured to detect the one or more magnets associated with the sample support so as to identify a mode of operating the spectrometer corresponding to the sample support.

2. The sub-assembly of claim 1, wherein the sensor assembly includes one or more magnetic field sensors for detecting the one or more magnets.

3. The sub-assembly of claim 1, further including
a base mount adapted for mounting to a base of the sample compartment of the spectrometer, the base mount being associated with the sensor assembly.

4. The sub-assembly of claim 3, wherein the base mount defines an aperture for exposing a sensor portion of the sensor assembly such that sensor portion is aligned with the one or more magnets in use so as to facilitate detection of the one or more magnets by the sensor assembly.

5. The sub-assembly of claim wherein the sample support includes a mounting magnet for securing the sample support to the base mount.

6. The sub-assembly of claim 1, wherein the one or more magnets are mounted to an underside of the sample support for detection by the sensor assembly.

7. The sub-assembly of claim 2, wherein the one or more magnetic field sensors are arranged such that a position of each magnetic field sensor corresponds to a position of a magnet.

8. The sub-assembly of claim 1, wherein the sample support is associated with a plurality of magnets, and the sub-assembly further includes a magnetic keeper to mask one or more of the plurality of magnets so as to provide a plurality of unique combinations of exposed magnets for detection by the sensor assembly, each combination being associated with a specific mode of operation for the spectrometer.

9. The sub-assembly of claim 8, wherein the magnetic keeper comprises a mask defining a plurality of apertures therein, wherein movement of the mask relative to the plurality of magnets changes the combination of magnets exposed through the apertures thereby providing a plurality of unique combinations of exposed magnets.

10. The sub-assembly of claim 9, wherein movement of the mask includes rotation of the mask and reversing of the mask.

11. The sub-assembly of claim 1, wherein the sensor assembly is coupled to a controller of the spectrometer to determine a mode of operation for the spectrometer corresponding to the sample support.

12. A spectrometer comprising a sample compartment sub-assembly of claim 1.

13. A spectrometer having a sample compartment, the spectrometer including
a sample support adapted to support one or more sample holders for use in the sample compartment, the sample support being associated with one or more magnets,
a base mount adapted for mounting to a base of the sample compartment of the spectrometer, the base mount having a sensor assembly associated therewith for detecting the one or more magnets associated with the sample support so as to identify a mode of operating the spectrometer corresponding to the sample support.

14. The spectrometer of claim 13, wherein the sensor assembly includes one or more magnetic field sensors for detecting the one or more magnets.

15. The spectrometer of claim 13, wherein the base mount defines an aperture for exposing a sensor portion of the sensor assembly such that sensor portion is aligned with the one or more magnets in use so as to facilitate detection of the one or more magnets by the sensor assembly.

16. The spectrometer of claim 13, wherein the sample support includes a mounting magnet for securing the sample support to the base mount in use.

17. The spectrometer of claim 13, wherein the one or more magnets are mounted to an underside of the sample support for detection by the sensor assembly.

18. The spectrometer of claim 14, wherein the one or more magnetic field sensors are arranged such that a position of each magnetic field sensor corresponds to a position of a magnet.

19. The spectrometer of claim 13, wherein the sample support is associated with a plurality of magnets, and the sub-assembly further includes a magnetic keeper to mask one or more of the plurality of magnets so as to provide a plurality of unique combinations of exposed magnets for detection by the sensor assembly, each combination being associated with a mode of operation for the spectrometer.

20-23. (canceled)

24. A system of auto-recognition of a sample accessory for a spectrometer, the system including
a plurality of magnets associated with the sample accessory, and
a sensor assembly mounted in a sample compartment of the spectrometer, the sensor assembly being configured to detect the plurality of magnets when the sample accessory is used in the sample compartment to determine a mode of operating the spectrometer corresponding to the sample accessory.

25-31. (canceled)
